(19) United States
(12) Patent Application Publication
(10) Pub. No.: US 2025/0254859 A1
(43) Pub. Date: Aug. 7, 2025

(54) SEMICONDUCTOR DEVICES

(71) Applicant: Samsung Electronics Co., Ltd., Suwon-si (KR)

(72) Inventors: Hyeran Lee, Suwon-si (KR); Taejin Park, Suwon-si (KR); Sungjoo Kang, Suwon-si (KR); Keunui Kim, Suwon-si (KR); Euijoong Shin, Suwon-si (KR); Hyeonkyu Lee, Suwon-si (KR); Hosang Lee, Suwon-si (KR); Seongeun Cho, Suwon-si (KR); Sangsuk Han, Suwon-si (KR)

(21) Appl. No.: 18/918,192

(22) Filed: Oct. 17, 2024

(30) Foreign Application Priority Data
Feb. 5, 2024 (KR) 10-2024-0017242

(51) Int. Cl. H10B 12/00

(52) U.S. Cl. CPC H10B 12/315; H10B 12/05

(57) ABSTRACT

A semiconductor device includes a vertical pattern including a first source/drain region, a second source/drain region on a level higher than that of the first source/drain region, and a vertical channel region between the first and second source/drain regions; and a gate structure disposed on a first side surface of the vertical pattern, wherein the gate structure includes a gate electrode including a gate electrode liner on the first surface of the vertical pattern and a gate electrode material layer on the gate electrode liner; a gate dielectric layer including a portion disposed between the vertical pattern and the gate electrode liner of the gate electrode; and at least one insulating barrier layer extending along at least one side of the gate electrode liner on the gate dielectric layer, wherein the at least one insulating barrier layer has a liner shape, with the gate electrode liner.

### CROSS-REFERENCE TO RELATED APPLICATION(S)

This application claims benefit of priority under 35 U.S.C. § 119 to Korean Patent Application No. 10-2024-0017242, filed on Feb. 5, 2024, in the Korean Intellectual Property Office, the content of which is incorporated herein by reference in its entirety.

### BACKGROUND

The present inventive concept relates to a semiconductor device.

As demands for high performance, high speed, and/or multifunctionality of semiconductor devices increase, a degree of integration of such semiconductor devices is increasing. In manufacturing semiconductor devices having a fine pattern in response to the trend for a high degree of integration of the semiconductor devices, it is necessary to implement patterns with a fine width or a fine spacing distance.

### SUMMARY

An aspect of the present inventive concept is to provide a semiconductor device including at least one barrier layer to prevent and/or minimize current leakage that may occur between a gate electrode and a bit line structure and/or between the gate electrode and contact patterns.

According to an aspect of the present inventive concept, a semiconductor device includes a bit line structure extending in a first horizontal direction; a first vertical pattern and a second vertical pattern, disposed on the bit line structure and spaced apart from each other; a first back gate structure and a second back gate structure, respectively extending in a second horizontal direction, intersecting the first horizontal direction, and parallel to each other, on the bit line structure; and a plurality of gate structures between the first back gate structure and the second back gate structure, wherein each of the first and second vertical patterns includes a first source/drain region electrically connected to the bit line structure; a second source/drain region on a level higher than that of the first source/drain region; and a vertical channel region between the first and second source/drain regions, wherein the vertical channel regions of the first and second vertical patterns are disposed between the first and second back gate structures, wherein the plurality of gate structures include a first gate structure adjacent to the first vertical pattern, and a second gate structure adjacent to the second vertical pattern, wherein the first gate structure includes a first gate electrode including a first liner on the first vertical pattern and a first gate electrode material layer on the first liner; a first gate dielectric layer including a portion disposed between the first vertical pattern and the first gate electrode; and at least one first barrier layer extending along at least one side of the first liner on the first gate dielectric layer, wherein the second gate structure includes a second gate electrode including a second liner on the second vertical pattern and a second gate electrode material layer on the second liner; a second gate dielectric layer including a portion disposed between the second vertical pattern and the second gate electrode; and at least one second barrier layer extending along at least one side of the second liner on the second gate dielectric layer.

According to an aspect of the present inventive concept, a semiconductor device includes a vertical pattern including a first source/drain region, a second source/drain region on a level higher than that of the first source/drain region, and a vertical channel region between the first and second source/drain regions; a back gate structure facing a first side surface of the vertical pattern; and a gate structure facing a second side surface, opposite to the first side surface of the vertical pattern, wherein the back gate structure includes a back gate electrode on the first side surface of the vertical pattern; and a back gate dielectric layer including a portion disposed between the vertical pattern and the back gate electrode, wherein the gate structure includes a gate electrode including a gate electrode liner on the second surface of the vertical pattern and a gate electrode material layer on the gate electrode liner; a gate dielectric layer including a portion disposed between the vertical pattern and the gate electrode liner of the gate electrode; and at least one barrier layer extending along at least one side of the gate electrode liner on the gate dielectric layer.

According to an aspect of the present inventive concept, a semiconductor device includes a vertical pattern including a first source/drain region, a second source/drain region on a level higher than that of the first source/drain region, and a vertical channel region between the first and second source/drain regions; and a gate structure disposed on a first side surface of the vertical pattern, wherein the gate structure includes a gate electrode including a gate electrode liner on the first surface of the vertical pattern and a gate electrode material layer on the gate electrode liner; a gate dielectric layer including a portion disposed between the vertical pattern and the gate electrode liner of the gate electrode; and at least one insulating barrier layer extending along at least one side of the gate electrode liner on the gate dielectric layer, wherein the at least one insulating barrier layer has a liner shape with the gate electrode liner.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor device according to an example embodiment.

FIG. 2 is a vertical cross-sectional view of the semiconductor device illustrated in FIG. 1, taken along line I-I′.

FIG. 3A is an enlarged view of a portion of the semiconductor device illustrated in FIG. 2.

FIG. 3B is an enlarged view of a portion of the semiconductor device illustrated in FIG. 3A.

FIGS. 4 to 7 are partially enlarged views of semiconductor devices according to example embodiments.

FIGS. 8 to 24 are vertical cross-sectional views illustrated according to a process sequence to explain a method of manufacturing a semiconductor device according to an example embodiment.

FIGS. 25 and 26 are vertical cross-sectional views illustrated according to a process sequence to explain a method of manufacturing a semiconductor device according to an example embodiment.

### DETAILED DESCRIPTION

Hereinafter, preferred embodiments of the present inventive concept will be described with reference to the attached drawings. Like reference characters refer to like elements throughout.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

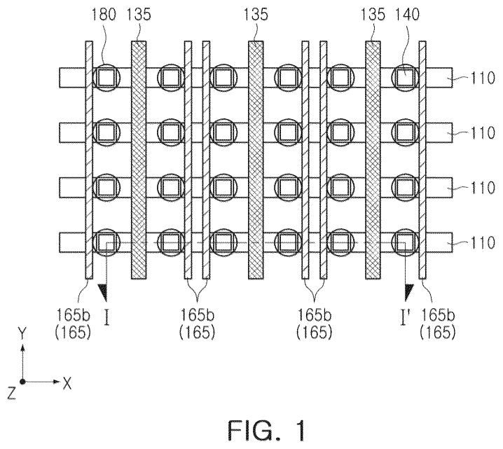

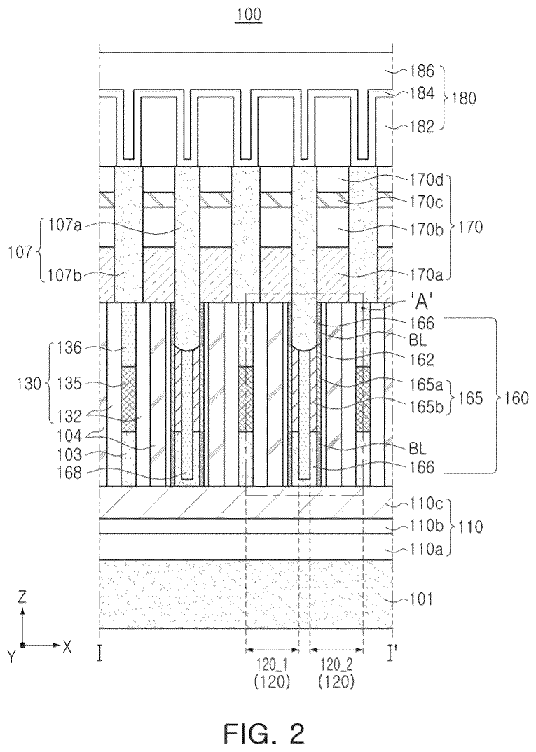

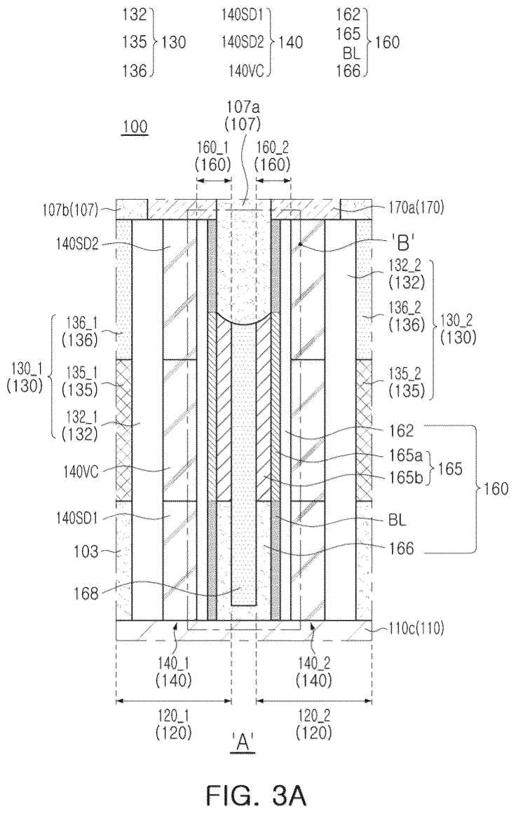

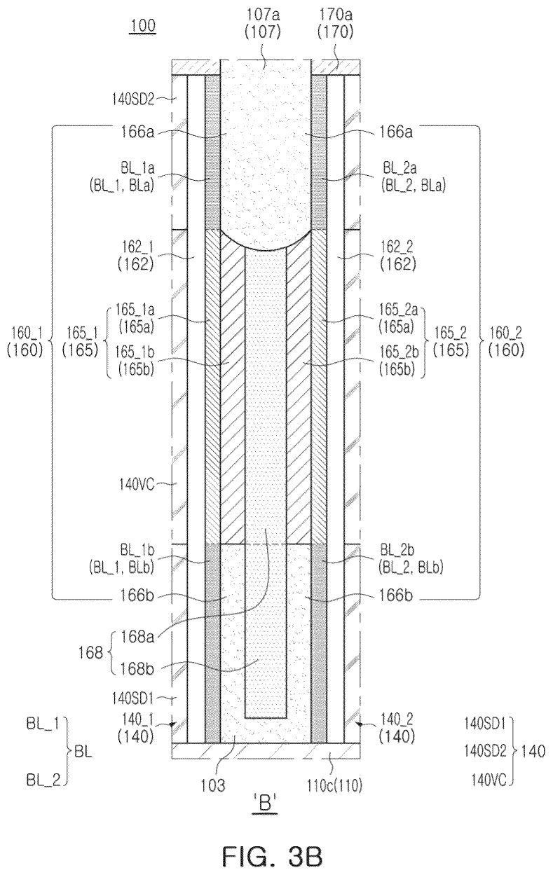

FIG. 1 is a plan view of a semiconductor device according to an example embodiment. FIG. 2 is a vertical cross-sectional view of the semiconductor device illustrated in FIG. 1, taken along line I-I′. FIG. 3A is a partially enlarged view of portion ‘A’ of the semiconductor device illustrated in FIG. 2. FIG. 3B is a partially enlarged view of portion ‘B’ of the semiconductor device illustrated in FIG. 3A.

Referring to FIGS. 1 to 3B, a semiconductor device 100 may include lower insulating layers 101, a bit line structure 110 extending on the lower insulating layers 101 in a first horizontal direction, for example, an X-direction, line structures 120 spaced apart from each other on the lower insulating layers 101 and the bit line structure 110 and extending in a second horizontal direction, for example, a Y-direction, an intermediate insulating layer 103 covering the line structures 120 on the lower insulating layers 101 and the bit line structure 110, upper insulating layers 107 on the intermediate insulating layer 103, information storage structures 180 on the upper insulating layers 107, and contact patterns 170 passing through the upper insulating layers 107 and connecting the line structures 120 and the information storage structures 180.

In an example embodiment, the line structures 120 may include a first line structure 120_1 and a second line structure 120_2, spaced apart from each other in the first horizontal direction (X-direction) and extending lengthwise in parallel in the second horizontal direction (Y-direction). The first horizontal direction (X-direction) may be perpendicular to the second horizontal direction (Y-direction).

Each of the line structures 120 may include a vertical pattern 140, a back gate structure 130 disposed on one side of the vertical pattern 140, and a gate structure 160 disposed on a side of vertical patterns 140, opposite to the one side. Each of the vertical patterns 140 may include a first source/drain region 140SD1, a second source/drain region 140SD2 on a level higher than that of the first source/drain region 140SD1, and a vertical channel region 140VC between the first and second source/drain regions 140SD1 and 140SD2. Each of the vertical patterns 140 may be arranged intermittently in the second horizontal direction (Y-direction).

The semiconductor device 100 may include a vertical channel transistor including vertical patterns 140, a bit line structure 110 electrically connected to the vertical patterns 140, and gate structures 160 disposed on at least one side of the vertical patterns 140.

The semiconductor device 100 may be applied to, for example, a cell array of a dynamic random access memory (DRAM), but the present inventive concept is not limited thereto.

The lower insulating layers 101 may include an insulating material such as silicon oxide, silicon nitride, silicon oxynitride (SiON), silicon carbonitride (SiCN), or the like.

In an example embodiment, the lower insulating layer 101 may include a plurality of lower insulating layers (not illustrated). In this case, an insulating layer disposed in an uppermost portion of the plurality of lower insulating layers may be, for example, an insulating layer covering a lower surface of the bit line structure 110. Additionally, an insulating layer disposed in a lowermost portion of the plurality of lower insulating layers may be an adhesive layer for adhering to another structure. Depending on embodiments, the number of layers and a material of the lower insulating layer 101 may be changed.

The bit line structure 110 may extend lengthwise on the lower insulating layer 101 in the first horizontal direction (X-direction). In an example embodiment, the bit line structure 110 may be buried within the lower insulating layer 101. For example, the lower insulating layer 101 may cover a lower portion surface and side surfaces of the bit line structure 110. For example, the lower insulating layer 101 may contact the lower portion surface and side surfaces of the bit line structure 110.

The bit line structure 110 may be electrically connected to the vertical pattern 140. For example, the bit line structure 110 may be in contact with and be electrically connected to the first source/drain region 140SD1 of the vertical pattern 140.

The bit line structure 110 may be provided as a plurality of bit line structures 110, and the plurality of bit line structures 110 may extend in parallel, and may be spaced apart from each other in a direction perpendicular to the first horizontal direction.

The bit line structure 110 may include doped polysilicon, metal, a conductive metal nitride, a metal-semiconductor compound, a conductive metal oxide, a conductive graphene, a carbon nanotube, or a combination thereof. For example, the bit line structure 110 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, a graphene, a carbon nanotube, or a combination thereof. In an example embodiment, the bit line structure 110 may include first to third conductive patterns 110a, 110b, and 110c, sequentially stacked on the lower insulating layer 101. The first conductive pattern 110a may be formed of or include a metal material such as titanium (Ti), tantalum (Ta), tungsten (W), and aluminum (Al), the second conductive pattern 110b may be formed of or include, for example, a metal nitride such as titanium nitride (TiN) or the like, or a silicide material such as titanium silicide (TiSi) or the like, and the third conductive pattern 110c may be formed of or include a semiconductor material such as polycrystalline silicon. The third conductive pattern 110c may be a layer doped with impurities. Depending on embodiments, a material, the number of layers, and a thickness of layers forming the bit line structure 110 may be changed.

Each of the vertical patterns 140 may include a first source/drain region 140SD1 contacting the bit line structure 110, a second source/drain region 140SD2 connected to the contact pattern 170, and a vertical channel region 140VC between the first and second source/drain regions 140SD1 and 140SD2.

In an example embodiment, the first and second source/drain regions 140SD1 and 140SD2 may have a first conductivity type, and the vertical channel region 140VC may have a second conductivity type, different from the first conductivity type, or may be an undoped intrinsic region. For example, the first conductivity type may be an N-type conductivity type, and the second conductivity type may be a P-type conductivity type.

In an example embodiment, vertical patterns 140 may include a single crystal semiconductor material. The single crystal semiconductor material may include a group IV semiconductor, a group III-V compound semiconductor, or a group II-VI compound semiconductor, and may be, for example, a single crystal semiconductor including at least one of silicon, silicon carbide, germanium, or silicon-germanium. Depending on embodiments, the vertical patterns 140 may include at least one of a polycrystalline semiconductor material, an oxide semiconductor material such as indium gallium zinc oxide (IGZO) or the like, or a two-dimensional material such as MoS₂ or the like.

The vertical patterns 140 may include first vertical patterns 140_1 arranged to be spaced apart from each other in the second horizontal direction (Y-direction), and second vertical patterns 140_2 arranged to be spaced apart from each other in the second horizontal direction (Y-direction) and spaced apart from the first vertical patterns 140_1 in the first horizontal direction (X-direction). The first vertical patterns 140_1 may be disposed on one side of the back gate structure 130, and the second vertical patterns 140_2 may be disposed on the other side of the back gate structure 130, opposite to the one side.

The back gate structures 130 may cross an upper portion surface of the bit line structure 110 on the lower insulating layer 101, and may extend lengthwise in the second horizontal direction (Y-direction).

The back gate structures 130 may include a first back gate structure 130_1 surrounding at least one side of the first vertical patterns 140_1 while extending in the second horizontal direction (Y-direction), and a second back gate structure 130_2 spaced apart from the first back gate structure 130_1 in the first horizontal direction (X-direction) and surrounding at least one side of the second vertical patterns 140_2 while extending in the second horizontal direction (Y-direction).

Each of the back gate structures 130 may include a back gate electrode 135 extending in the second horizontal direction (Y-direction), a dielectric structure 132 disposed on both sides of the back gate electrode 135, and a back gate capping layer 136 on the back gate electrode 135.

The back gate electrode 135 may serve to remove charges trapped within the vertical channel region 140VC of each of the vertical patterns 140. The vertical channel regions 140VC may be floating bodies, and the back gate electrode 135 may be a structure to complement a floated vertical channel region 140VC for preventing or minimizing performance degradation of the semiconductor device 100 due to a floating body effect of the vertical channel regions 140VC.

The back gate electrode 135 may be formed of or include doped polysilicon, metal, conductive metal nitride, metal-semiconductor compound, conductive metal oxide, graphene, carbon nanotube, or a combination thereof. For example, the back gate electrode 135 may be formed of doped polysilicon, Al, Cu, Ti, Ta, Ru, W, Mo, Pt, Ni, Co, TiN, TaN, WN, NbN, TiAl, TiAlN, TiAlC, TaAlC, TiSi, TiSiN, TaSi, TaSiN, RuTiN, NiSi, CoSi, IrOₓ, RuOₓ, graphene, carbon nanotube, or a combination thereof, but the present inventive concept is not limited thereto. The back gate electrode 135 may be formed as a single layer or multiple layers of the above-described materials.

In an example embodiment, the back gate electrode 135 may be formed of the same material as the gate electrode 165, but the present inventive concept is not limited thereto, and may include a different material.

The dielectric structures 132 may extend in the second horizontal direction (Y-direction) along both sides of the back gate electrode 135 on the lower insulating layers 101.

In an example embodiment, the dielectric structures 132 may include a first dielectric structure 132_1 disposed on one side of the back gate electrode 135, and a second dielectric structure 132_2 disposed on the other side of the back gate electrode 135, opposite to the one side. The first dielectric structure 132_1 may include a portion disposed between the back gate electrode 135 and the first vertical patterns 140_1, and the second dielectric structure 132_2 may include a portion disposed between the back gate electrode 135 and the second vertical patterns 140_2.

The dielectric structures 132 may be disposed between the back gate electrode 135 and the vertical patterns 140, to space the back gate electrode 135 and the vertical patterns 140 apart from each other.

The dielectric structure 132 may contact side surfaces of the first and second source/drain regions 140SD1 and 140SD2 and the vertical channel regions 140VC. The dielectric structure 132 may contact side surfaces of the back gate electrode 135 and the back gate capping layer 136. In example embodiments, the back gate electrode 135 and the back gate capping layer 136 may be disposed between adjacent ones of the dielectric structures 132, and may contact side surfaces of the adjacent ones of the dielectric structures 132.

The dielectric structures 132 may include a different material than a gate dielectric layer 162. The dielectric structures 132 may include a material having a lower dielectric constant than the gate dielectric layer 162.

The back gate capping layer 136 may be disposed on the back gate electrode 135. The back gate capping layer 136 may be disposed to extend along at least one side of the dielectric structure 132. In an example embodiment, the back gate capping layer 136 may completely overlap the back gate electrode 135 in a vertical direction (Z-direction). The back gate capping layer 136 may contact an upper surface of the back gate electrode 135. In an example embodiment, a first back gate capping layer 136_1 may extend along at least one side of the first dielectric structure 132_1 on a first back gate electrode 135_1. For example, the first back gate capping layer 136_1 may contact the at least one side of the first dielectric structure 132_1 and an upper surface of the first back gate electrode 135_1.

The back gate capping layer 136 may include an insulating material such as silicon oxide, silicon nitride, silicon oxynitride (SiON), silicon carbonitride (SiCN), or the like. In an example embodiment, the back gate capping layer 136 may include a different material than the intermediate insulating layer 103. The back gate capping layer 136 may include, for example, silicon nitride.

The gate structures 160 may extend from both sides of the back gate structure 130 in the second horizontal direction (Y-direction). The gate structures 160 may be spaced apart from each other in the first horizontal direction (X-direction), and may extend lengthwise in parallel in the second horizontal direction (Y-direction). The gate structures 160 may be spaced apart from the back gate structure 130 in the first horizontal direction (X-direction).

The gate structures 160 may include a first gate structure 160_1 surrounding at least one side of the first vertical patterns 140_1 while extending lengthwise in the second horizontal direction (Y-direction), and a second gate structure 160_2 spaced apart in the first horizontal direction (X-direction) and surrounding at least one side of the second vertical patterns 140_2 while extending lengthwise in the second horizontal direction (Y-direction).

Each of the gate structures 160 may include a gate dielectric layer 162, a gate electrode 165, and a gate capping layer 166. The first gate structure 160_1 may include a first gate dielectric layer 162_1, a first gate electrode 165_1, and a first gate capping layer 166a, and the second gate structure 160_2 may include a second gate dielectric layer 162_2, a second gate electrode 165_2, and a second gate capping layer 166b.

The gate dielectric layer 162 may be disposed between the gate electrode 165 and the vertical patterns 140, on the lower insulating layer 101. The gate dielectric layer 162 may contact side surfaces of the gate electrode 165 and the vertical patterns 140.

In an example embodiment, the gate dielectric layer 162 may be disposed to conformally cover a side surface of the back gate structure 130, and side surfaces of the vertical patterns 140 disposed on the side surface of the back gate structure.

In an example embodiment, the gate dielectric layer 162 may have substantially the same length in the vertical direction (Z-direction), as the vertical patterns 140. For example, the gate dielectric layer 162 may have a lower surface contacting an upper surface of the bit line structure 110 and an upper surface contacting a lower surface of the contact pattern 170, and a length of the gate dielectric layer 162 may refer to a distance of the gate dielectric layer 162 between the lower surface and the upper surface. In example embodiments, upper surfaces of the gate dielectric layer 162 and the vertical patterns 140 may be coplanar, and lower surfaces of the gate dielectric layer 162 and the vertical patterns 140 may be coplanar.

The gate dielectric layer 162 may include at least one of silicon oxide or a high-k dielectric. The high-K dielectric may include metal oxide or metal oxynitride. For example, the high-K dielectric may be formed of HfO₂, HfSiO, HfSiON, HfTaO, HfTiO, HfZrO, ZrO₂, Al₂O₃, or a combination thereof, but the present inventive concept is not limited thereto. The gate dielectric layer 162 may be formed as a single layer or multiple layers of the materials described above.

The gate electrode 165 may be disposed on at least one side of the gate dielectric layer 162 on the lower insulating layers 101. The gate electrode 165 may be spaced apart from the vertical patterns 140 by the gate dielectric layer 162. In an example embodiment, the first gate electrode 165_1 may be spaced apart from the first vertical patterns 140_1 by the first gate dielectric layer 162_1.

Each of the gate electrodes 165 may include a gate electrode liner 165a and a gate electrode material layer 165b. In an example embodiment, the first gate electrode 165_1 may include a first gate electrode liner 165_1a and a first gate electrode material layer 165_1b, and the second gate electrode 165_2 may include a second gate electrode liner 165_2a and a second gate electrode material layer 165_2b.

The gate electrode material layer 165b may be disposed on at least one side of the gate dielectric layer 162, and the gate electrode liner 165a may be disposed between the gate dielectric layer 162 and the gate electrode material layer 165b. The gate electrode liner 165a may contact side surfaces of the gate dielectric layer 162 and the gate electrode material layer 165b. A thickness of the gate electrode liner 165a may be 10 Å or less, for example, 2 Å to 10 Å, or 2 Å to 8 Å, or 4 Å to 6 Å. A thickness of the gate electrode material layer 165b may be 50 Å or less, for example, 35 Å to 50 Å, or 40 Å to 50 Å, or 40 Å to 45 Å. Therefore, a thickness of the gate electrode 165 may be 60 Å or less, for example, 50 Å to 60 Å, or 50 Å to 55 Å. The thicknesses of the gate electrode liner 165a, the gate electrode material layer 165b, and the gate electrode 165 may refer to widths of the gate electrode liner 165a, the gate electrode material layer 165b, and the gate electrode 165 in the first direction (X-direction).

The gate electrode 165 may include doped polysilicon, metal, a conductive metal nitride, a metal-semiconductor compound, a conductive metal oxide, a conductive graphene, a carbon nanotube, or a combination thereof. For example, the gate electrode 165 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, a graphene, a carbon nanotube, or a combination thereof, but the present inventive concept is not limited thereto. In the present embodiment, the gate electrode material layer 165b may include a metal material, such as Mo, and the gate electrode liner 165a may be selected from conductive metal oxides, such as the group consisting of TiSiN, TaSiN, TiN, or TaN.

The gate structures 160 may further include at least one barrier layer BL extending along at least one side of the gate electrode liner 165a on at least one side of the gate dielectric layer 162. In an example embodiment, the first gate structures 160_1 may include at least one first barrier layer BL_1, and the second gate structures 160_2 may include at least one second barrier layer BL_2. The at least one first barrier layer BL_1 may be disposed between the first gate dielectric layer 162_1 and the intermediate insulating layer 103, and the at least one second barrier layer BL_2 may be disposed between the second gate dielectric layer 162_2 and the intermediate insulating layer 103. For example, the at least one first barrier layer BL_1 may contact side surfaces of the first gate dielectric layer 162_1 and the intermediate insulating layer 103, and the at least one second barrier layer BL_2 may contact side surfaces of the second gate dielectric layer 162_2 and the intermediate insulating layer 103. The at least one first barrier layer BL_1 and the at least one second barrier layer BL_2 may contact upper surfaces of the bit line structure 110.

In the present embodiment, the at least one barrier layer BL may include a plurality of barrier layers. For example, in the present embodiment, the plurality of barrier layers may include a first portion BLa extending from one surface of the gate electrode liner 165a in a vertical direction, for example, vertically in an upward direction, and a second portion BLb extending from the other surface of the gate electrode liner 165a, opposite to the one surface, in a vertical direction, for example, vertically in a downward direction.

The first portion BLa of the at least one first barrier layer BL_1, also referred to as first portion BL_1a, may be disposed between the first gate dielectric layer 162_1 and the first gate capping layer 166a, and the first portion BLa of the at least one second barrier layer BL_2, also referred to as second portion BL_2a, may be disposed between the second gate dielectric layer 162_2 and the first gate capping layer 166a. For example, the first portion BLa of the at least one first barrier layer BL_1 may contact side surfaces of the first gate dielectric layer 162_1 and the first gate capping layer 166a, and the first portion BLa of the at least one second barrier layer BL_2 may contact side surfaces of the second gate dielectric layer 162_2 and the first gate capping layer 166a. The first portions BLa of the at least one first barrier layer BL_1 and the at least one second barrier layer BL_2 may contact lower surfaces of contact patterns 170.

The second portion BLb of the at least one first barrier layer BL_1 also referred to as second portion BL_1b, may be disposed between the first gate dielectric layer 162_1 and the intermediate insulating layer 103, and the second portion BLb of the at least one second barrier layer BL_2 also referred to as second portion BL_2b, may be disposed between the second gate dielectric layer 162_2 and the intermediate insulating layer 103. For example, the second portion BLb of the at least one first barrier layer BL_1 may contact side surfaces of the first gate dielectric layer 162_1 and the intermediate insulating layer 103, and the second portion BLb of the at least one second barrier layer BL_2 may contact side surfaces of the second gate dielectric layer 162_2 and the intermediate insulating layer 103. The second portions BLb of the at least one first barrier layer BL_1 and the at least one second barrier layer BL_2 may contact upper surfaces of the bit line structure 110.

Each of the barrier layers BL may have a liner shape, with the gate electrode liner 165a. For example, each of the barrier layers BL and the gate electrode liner 165a may be physically and integratedly connected to each other. For example, the first portion BLa of the barrier layer may have a liner shape with the one surface of the gate electrode liner 165a, and the second portion BLb of the barrier layer may have a liner shape with the other surface of the gate electrode liner 165a. For example, the first portion BLa of the barrier layer may contact an upper surface of the gate electrode liner 165a, and the second portion BLb of the barrier layer may contact a lower surface of the gate electrode liner 165a. The barrier layer BL may include an oxide of a material included in the gate electrode liner 165a. Additionally, a thickness of each of the barrier layers BL may be substantially the same as a thickness of the gate electrode liner 165a. For example, a width in the first horizontal direction (X-direction) of each of the barrier layers BL may be substantially the same as a width in the first horizontal direction (X-direction) of the gate electrode liner 165a.

The barrier layer BL may be, for example, an oxide of a material selected from the group consisting of TiSiN, TaSiN, TiN, or TaN. Therefore, current leakage that may occur between the gate electrode 165 and the bit line structure 110 and/or between the gate electrode 165 and the contact patterns 170 may be prevented or minimized by the barrier layer BL.

The gate electrode 165 may have a length shorter than a length of the gate dielectric layer 162 or a length of each of the vertical patterns 140 in the vertical direction (Z-direction). A plurality of insulating layers may be disposed above and below the gate electrode 165. For example, a first gate capping layer 166a may be disposed above the gate electrode 165, and a second gate capping layer 166b may be disposed below the gate electrode 165. In this case, an upper portion of the first gate capping layer 166a may be connected to a lower portion of the upper insulating layers 107, and the first gate capping layer 166a and the upper insulating layers 107 may include the same material. The second gate capping layer 166b may be a portion of the intermediate insulating layer 103 described above. The plurality of insulating layers may be used to prevent the gate electrode 165 and the first and second source/drain regions 140SD1 and 140SD2 from overlapping in the horizontal direction, perpendicular to the vertical direction (Z-direction).

An insulating layer 168 may be additionally disposed between the first gate structure 160_1 and the second gate structure 160_2 to space the first gate electrode 165_1 and the second gate electrode 165_2 in the first horizontal direction (X-direction).

In the present embodiment, the insulating layer 168 may include a first portion 168a disposed between the first gate electrode 165_1 and the second gate electrode 165_2, and a second portion 168b extending downward from the first portion 168a.

The first portion 168a may have an upper surface contacting at least a portion of a lower surface of the first gate capping layer 166a. The upper surface of the first portion 168a may have a downwardly concave shape, and accordingly, the lower surface of the first gate capping layer 166a may also have a downwardly convex shape.

The second portion 168b may be a protrusion extending downward from the first portion 168a. A lower surface of the second portion 168b may be on a level higher than that of an upper surface of the bit line structure 110. Therefore, side and lower surfaces of the second portion 168b may be surrounded by the second gate capping layer 166b (or ‘intermediate insulating layer 103’).

The insulating layer 168 may include an insulating material such as silicon oxide, silicon nitride, silicon oxynitride (SiON), silicon carbonitride (SiCN), or the like.

The intermediate insulating layer 103 may cover a side surface of the line structures 120, along with upper surfaces of the bit line structures 110 and the lower insulating layers 101. The intermediate insulating layer 103 may include an insulating material such as silicon nitride, silicon oxynitride (SiON), silicon carbonitride (SiCN), or the like.

The upper insulating layers 107 may include a first upper insulating layer 107a disposed on the gate structure 160, and a second upper insulating layer 107b disposed on the back gate structure 130.

At least a portion of a lower region of the first upper insulating layer 107a may form a gate capping layer (or ‘first gate capping layer 166a’) of the gate structure 160. The at least a portion of the lower region of the first upper insulating layer 107a may be in contact with the upper surface of the insulating layer 168.

The second upper insulating layer 107b may cover at least a portion of an upper surface of the back gate structure 130. A lower surface of the second upper insulating layer 107b may be on a level higher than that of a lower surface of the first upper insulating layer 107a.

The upper insulating layers 107 may include an insulating material such as silicon nitride, silicon oxynitride (SiON), silicon carbonitride (SiCN), or the like. In an example embodiment, the upper insulating layer 107 may be provided as insulating layers (not illustrated), formed as a plurality of layers sequentially stacked.

The contact patterns 170 may pass through the upper insulating layers 107 to contact the vertical patterns 140 and be electrically connected to the vertical patterns 140. The contact patterns 170 may be in contact with the second source/drain region 140SD2 of the vertical patterns 140. The contact patterns 170 may electrically connect the vertical patterns 140 and the information storage structure 180.

A lower surface of the contact patterns 170 may be in contact with upper surfaces of the vertical patterns 140, the gate dielectric layer 162, and the dielectric structure 132 of the back gate structure 130, respectively.

The contact patterns 170 may include a conductive material, such as doped single crystal silicon, doped polycrystalline silicon, metal, a conductive metal nitride, a metal-semiconductor compound, a conductive metal oxide, a conductive graphene, a carbon nanotube, or a combination thereof. In an example embodiment, the contact patterns 170 may include first to fourth contact layers 170a, 170b, 170c, and 170d sequentially stacked. For example, the fourth contact layer 170d may contact an upper surface of the third contact layer 170c, the third contact layer 170c may contact an upper surface of the second contact layer 170b, and the second contact layer 170b may contact an upper surface of the first contact layer 170a. The first contact layer 170a may include doped single crystal silicon, the second contact layer 170b may include doped polycrystalline silicon, the third contact layer 170c may include a silicide material, and the fourth contact layer 170d may include metal. Depending on embodiments, the number of layers and a type of a material of the contact patterns 170 may be changed.

The information storage structures 180 may include first electrodes 182 electrically connected to the contact patterns 170, a second electrode 186 covering the first electrodes 182, and a dielectric layer 184 between the first electrodes 182 and the second electrode 186. The dielectric layer 184 may contact the first electrodes 182 and the second electrode 186.

In an example embodiment, the information storage structures 180 may be capacitors that store information in a DRAM. For example, the dielectric layer 184 of the information storage structures 180 may be a capacitor dielectric layer of a DRAM, and the dielectric layer 184 may include a high-K dielectric, silicon oxide, silicon nitride, silicon oxynitride, or a combination thereof.

Depending on embodiments, the information storage structures 180 may be structures that store information of a DRAM and other memory. For example, the dielectric layer 184 of the information storage structures 180 may be a capacitor dielectric layer of a ferroelectric memory (FeRAM). In this case, the dielectric layer 184 may be a ferroelectric layer that may record data using a polarization state. The ferroelectric layer, in another embodiment the dielectric layer 184 may also include a lower dielectric layer including at least one of silicon oxide or a high-K dielectric, and a ferroelectric layer disposed on the lower dielectric layer.

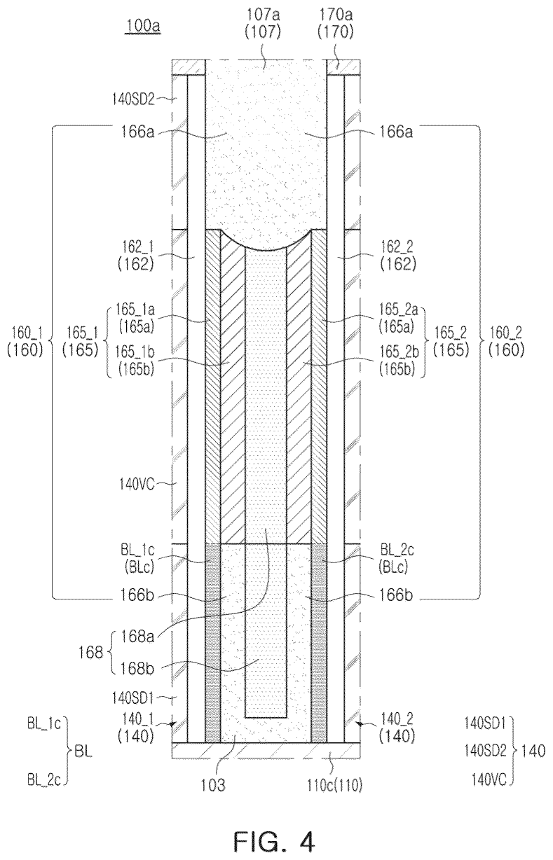

Hereinafter, various modifications of the components of the above-described embodiment will be described with reference to FIGS. 4 to 7. Various modifications of the components of the above-described embodiments described below will be described with a focus on modified or replaced components. In addition, the components that may be modified or replaced below may be described with reference to the drawings below, but the components that may be modified or replaced may be combined with each other or with the components described above, to configure a semiconductor device according to an embodiment.

FIGS. 4 to 7 are partially enlarged views of semiconductor devices according to example embodiments. FIGS. 4 to 7 illustrate enlarged images of a region corresponding to portion ‘B’ in FIG. 3B.

Referring to FIG. 4, a semiconductor device 100a may be identical or similar to that described with reference to FIGS. 1 to 3B, except that a barrier layer BL is disposed limitedly on one side of a back gate electrode 135.

Referring to FIG. 4, the barrier layer BL may include a lower barrier layer BLc extending from one surface of a gate electrode liner 165a on a gate dielectric layer 162 in a vertical direction, for example, vertically in a downward direction. For example, the barrier layer BL in the present embodiment may be disposed limitedly on a side of a bit line structure 110. For example, the barrier layer BL of the present embodiment may not include a barrier layer extending from the other surface of the gate electrode liner 165a, opposite to the one surface, on the gate dielectric layer 162 in a vertical direction, for example, vertically in an upward direction.

The lower barrier layer BLc may include a first lower barrier layer BL_1c and a second lower barrier layer BL_2c. The first lower barrier layer BL_1c may be disposed between the first gate dielectric layer 162_1 and the intermediate insulating layer 103, and the second lower barrier layer BL_2c may be disposed between the second gate dielectric layer 162_2 and the intermediate insulating layer 103. For example, the first lower barrier layer BL_1c may contact side surfaces of the first gate dielectric layer 162_1 and the intermediate insulating layer 103, and the second lower barrier layer BL_2c may contact side surfaces of the second gate dielectric layer 162_2 and the intermediate insulating layer 103. The lower barrier layer BLc may contact upper surfaces of the bit line structure 110.

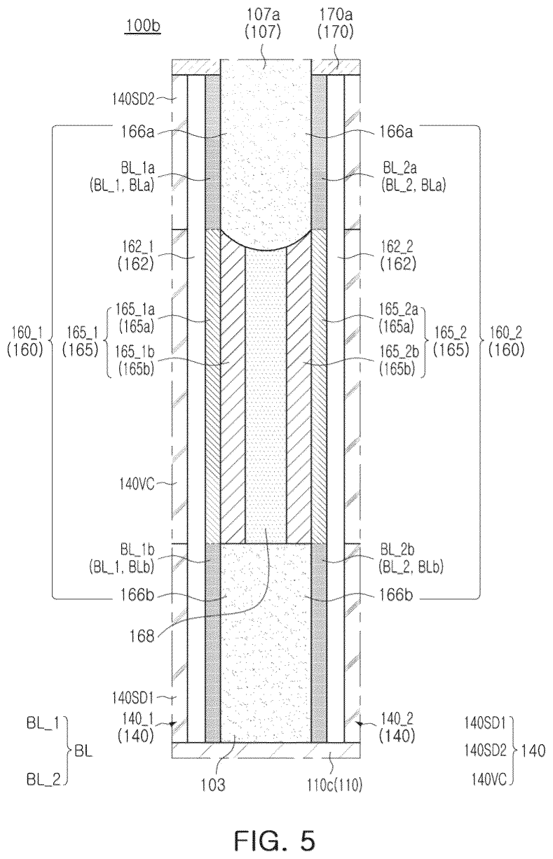

Referring to FIG. 5, a semiconductor device 100b may be identical or similar to that described with reference to FIGS. 1 to 4, except that a lower surface of an insulating layer 168 is on substantially the same level as lower surfaces of first and second gate electrodes 165_1 and 165_2.

Referring to FIG. 5, the lower surface of the insulating layer 168 may be coplanar with the lower surfaces of the first and second gate electrodes 165_1 and 165_2. For example, the insulating layer 168 may be disposed limitedly between the first gate electrode 165_1 and the second gate electrode 165_2. Therefore, an upper surface of an intermediate insulating layer 103 may be in contact with the lower surface of the insulating layer 168 and the lower surfaces of the first and second gate electrodes 165_1 and 165_2, and the upper surface of the intermediate insulating layer 103 may be planar.

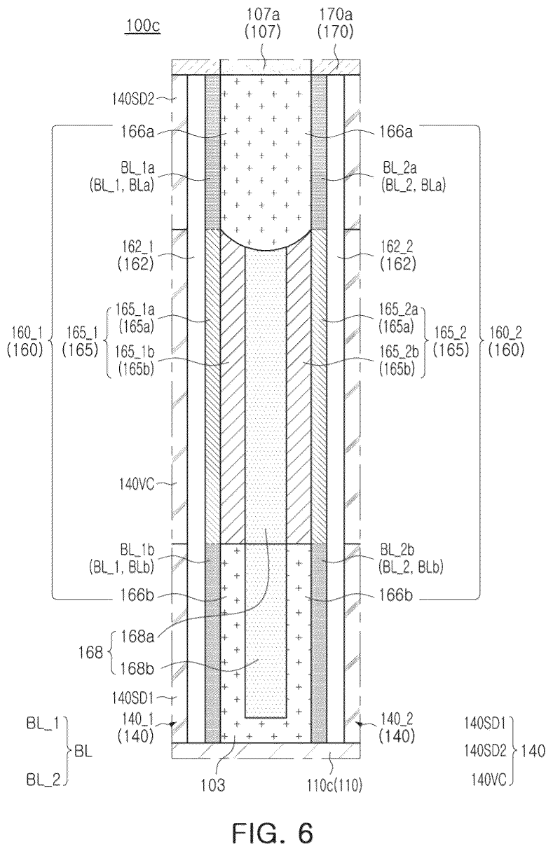

Referring to FIG. 6, a semiconductor device 100c may be identical or similar to that described with reference to FIGS. 1 to 5, except that an intermediate insulating layer 103 and/or an upper insulating layer 107 may include an oxide.

Referring to FIG. 6, the intermediate insulating layer 103 and/or the upper insulating layer 107 may include, for example, silicon oxide.

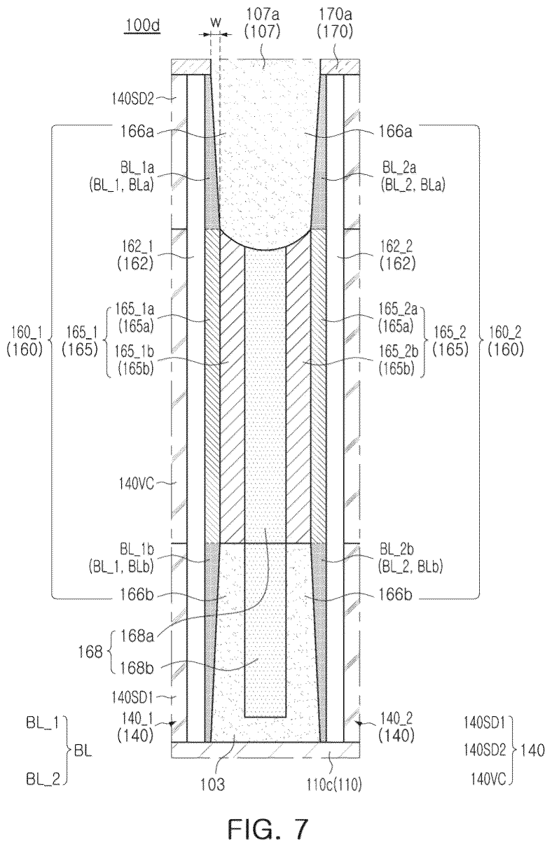

Referring to FIG. 7, a semiconductor device 100d may be identical or similar to that described with reference to FIGS. 1 to 6, except that a barrier layer BL has a tapering structure.

Referring to FIG. 7, a horizontal width w (or thickness) of the barrier layer BL may decrease, as the barrier layer BL extends along at least one side of a gate electrode liner 165a. For example, the horizontal width w may decrease, as a first portion BLa of the barrier layer BL extends from one surface of the gate electrode liner 165a in a vertical direction, for example, vertically in an upward direction. Additionally, the horizontal width w may decrease, as a second portion BLb of the barrier layer BL extends from the other surface of the gate electrode liner 165a, opposite to the one surface, in a vertical direction, for example, vertically in a downward direction.

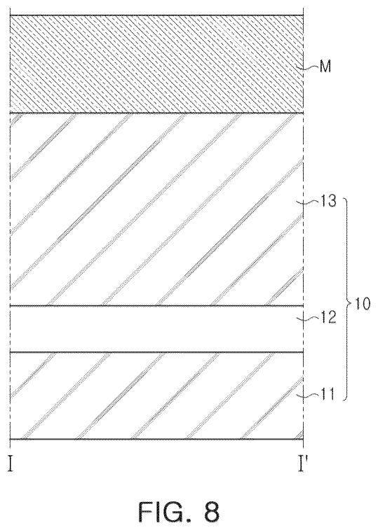

FIGS. 8 to 24 are vertical cross-sectional views illustrated according to a process sequence to explain a method of manufacturing a semiconductor device 100 according to an example embodiment.

Referring to FIG. 8, a semiconductor substrate 10 and a mask M on the semiconductor substrate 10 may be provided.

The semiconductor substrate 10 may be a silicon-on-insulator (SOI) substrate. The semiconductor substrate 10 may include a lower semiconductor layer 11, an insulating layer 12, and an upper semiconductor layer 13. For example, the upper and lower semiconductor layers 11 and 13 may include single crystal silicon.

The mask M may be subsequently used in an etching process to form a back gate trench BGT.

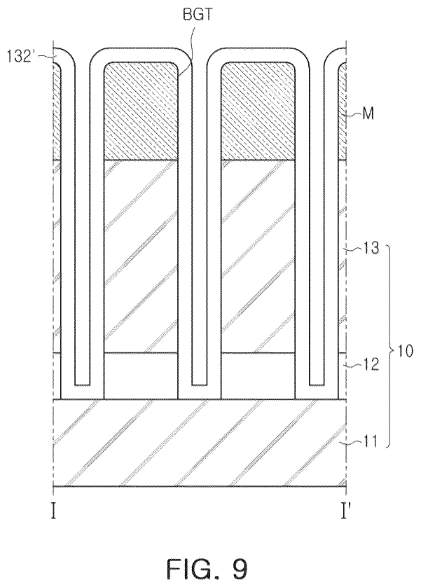

Referring to FIG. 9, the back gate trench BGT may be formed in the semiconductor substrate 10, and a preliminary back gate insulating layer 132′ may be formed in the back gate trench BGT.

The etching process using the mask M may be performed to form the back gate trench BGT passing through the upper semiconductor layer 13 and the insulating layer 12 and exposing an upper surface of the lower semiconductor layer 11. The back gate trench BGT may be formed in a linear shape extending in the second horizontal direction (Y-direction).

The preliminary back gate insulating layer 132′ may be formed on a sidewall of the back gate trench BGT. The preliminary back gate insulating layer 132′ may be deposited to cover substantially conformal to upper and side surfaces of the mask M, a side surface of the upper semiconductor layer 13, a side surface of the insulating layer 12, and an upper surface of the lower semiconductor layer 11. The preliminary back gate insulating layer 132′ may be formed by depositing an insulating material such as silicon oxide, silicon nitride, silicon oxynitride (SiON), silicon carbonitride (SiCN), or the like.

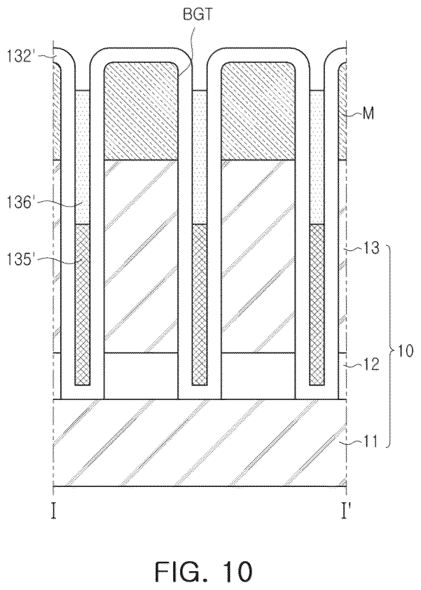

Referring to FIG. 10, a preliminary back gate electrode 135′ and a preliminary back gate capping layer 136′ may be formed in the back gate trench BGT.

The preliminary back gate electrode 135′ may be formed by depositing a conductive material to cover a surface of the preliminary back gate insulating layer 132′, and then at least portion thereof may be removed by an etch-back process. By the etch-back process, an upper surface of the preliminary back gate electrode 135′ may be formed between upper and lower surfaces of an upper semiconductor layer 13.

The preliminary back gate capping layer 136′ may be formed by depositing an insulating material on the preliminary back gate electrode 135′ to cover a surface of the preliminary back gate insulating layer 132′ and then performing an etch-back process. Through the etch-back process, an upper surface of the preliminary back gate capping layer 136′ may be formed between upper and lower surfaces of the mask M. In this case, upper surfaces of the preliminary back gate electrode 135′ and the preliminary back gate insulating layer 132′ may have a downwardly convex shape due to the etch-back processes.

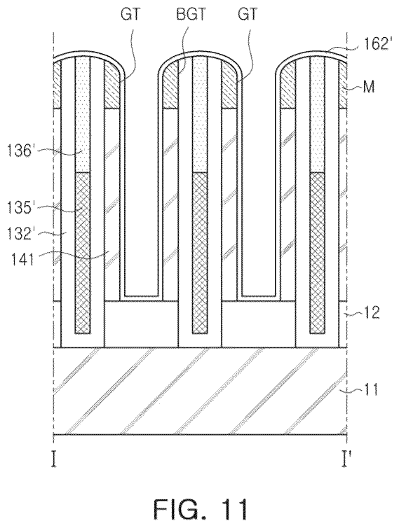

Referring to FIG. 11, a gate trench GT may be formed between back gate trenches BGT, and a preliminary gate dielectric layer 162′ may be formed within the gate trench GT.

By an etching process, the gate trench GT passing through the upper semiconductor layer 13 and exposing the upper surface of the insulating layer 12 may be formed. The gate trench GT may be formed in a linear shape extending in the second horizontal direction Y between the back gate trenches BGT. Vertical conductive layers 141 may be formed by the etching process.

By the etching process, a portion of the mask M and a portion of upper regions of structures formed in the back gate trenches BGT may also be removed. For example, by the etching process, an upper region of the mask M, an upper region of the preliminary back gate insulating layer 132′, and an upper region of the preliminary back gate capping layer 136′ formed in the back gate trenches BGT may be exposed.

The preliminary gate dielectric layer 162′ may be formed on a sidewall of the gate trench GT. The preliminary gate dielectric layer 162′ may be deposited to substantially conformally cover a side surface of the mask M, a side surface of the upper semiconductor layer 13, and an upper surface of the insulating layer 12.

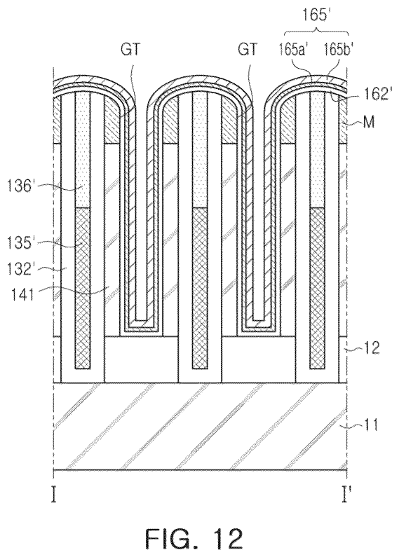

Referring to FIG. 12, a preliminary gate electrode 165′ may be formed in the gate trench GT.

The preliminary gate electrode 165′ may be formed by sequentially depositing a first conductive material forming a preliminary gate electrode liner 165a′ and a second conductive material forming a preliminary gate electrode material layer 165b′ to cover a surface of the gate trench GT. In the present inventive concept, the first conductive material may include a metal material containing Mo, and the second conductive material may be a material selected from the group consisting of TiSiN, TaSiN, TiN, or TaN.

The preliminary gate electrode 165′ may also be deposited on upper surfaces of the structures formed within the back gate trenches BGT, described with reference to FIG. 11.

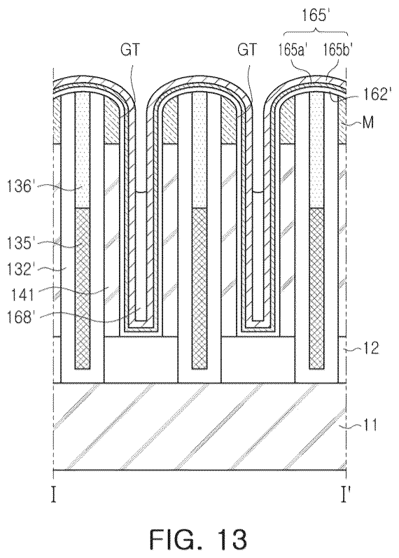

Referring to FIG. 13, a preliminary insulating layer 168′ may be formed within the gate trench GT.

The preliminary insulating layer 168′ may be formed by depositing an insulating material to cover a surface of the preliminary gate electrode material layer 165b′, and then at least a portion of the insulating material may be removed by an etch-back process. By the etch-back process, an upper surface of the preliminary insulating layer 168′ may be formed between upper and lower surfaces of the upper semiconductor layer 13.

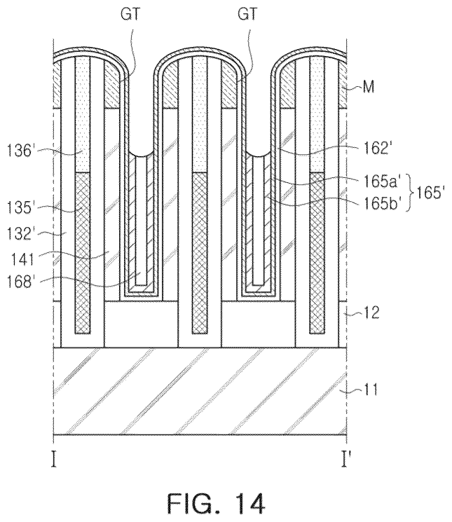

Referring to FIG. 14, at least a portion of the preliminary gate electrode material layer 165b′ may be removed in an etch-back process.

In the etch-back process, a portion of the preliminary gate electrode material layer 165b′ not covered by the preliminary insulating layer 168′, as illustrated in FIG. 13, may be selectively removed. Therefore, an upper surface of the preliminary gate electrode material layer 165b′ may have a downwardly convex shape like the upper surface of the preliminary insulating layer 168′.

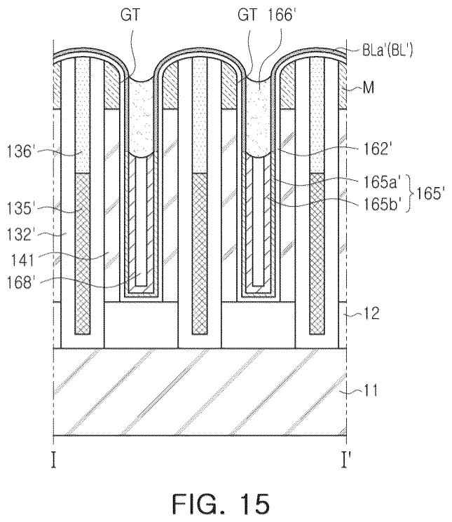

Referring to FIG. 15, at least a portion of the preliminary gate electrode liner 165a′ may be oxidized to form a preliminary barrier layer BL. After this, a preliminary insulating layer 166′ may be formed in the gate trench GT.

A portion of an exposed surface of a preliminary gate electrode liner 165a′ may be selectively oxidized. Therefore, a first preliminary portion BLa′ of the preliminary barrier layer BL may be formed (see FIG. 3A).

A preliminary insulating layer 166′ may be filled in the gate trench GT, and at least a portion thereof may be removed by an etch-back process, as necessary.

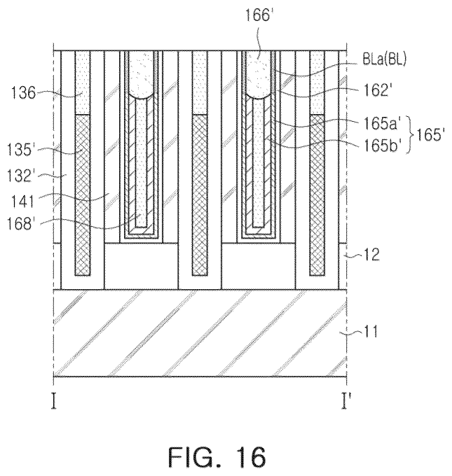

Referring to FIG. 16, an upper region of a semiconductor structure according to FIG. 15 may be planarized.

Referring to FIG. 16, the mask M disposed in the upper region of the semiconductor structure may be removed by a planarization process. Therefore, a first portion BLa of the barrier layer BL may be formed (see FIG. 3A).

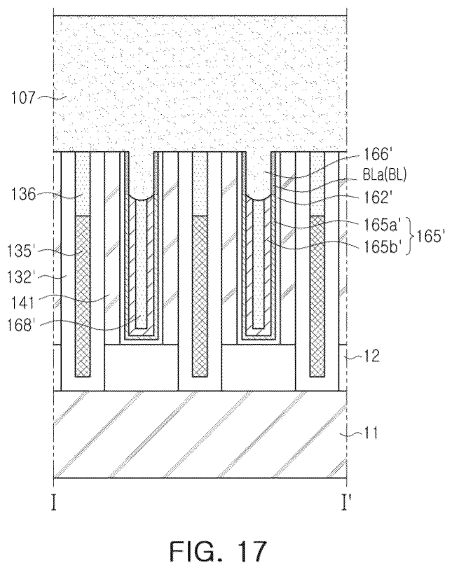

Referring to FIG. 17, an upper insulating layer 107 may be formed on an upper surface of the semiconductor structure according to FIG. 16.

The upper insulating layer 107 may be formed to cover the upper surface of the semiconductor structure according to FIG. 16. The upper insulating layer 107 may include the same material as the preliminary insulating layer 166′ according to FIG. 15. Although not illustrated, the preliminary insulating layer 166′ and the upper insulating layer 107 may have distinct boundaries even though they include the same material.

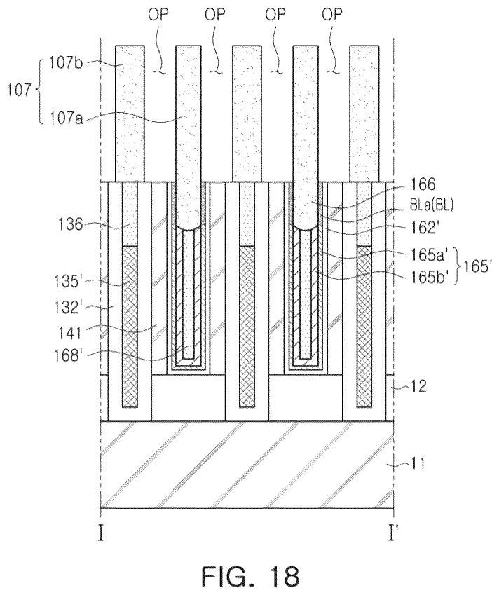

Referring to FIG. 18, a plurality of openings OP passing through the upper insulating layer 107 may be formed.

Referring to FIG. 18, the plurality of openings OP passing through the upper insulating layer 107 and exposing at least a portion of the upper surface of the semiconductor structure according to FIG. 16 may be formed. For example, upper surfaces of the vertical conductive layers 141 may be exposed by the plurality of openings OP.

A first upper insulating layer 107a disposed on the preliminary gate electrode material layer 165b′ and a second upper insulating layer 107b disposed on the preliminary back gate electrode 135′ may be formed by the plurality of openings OP.

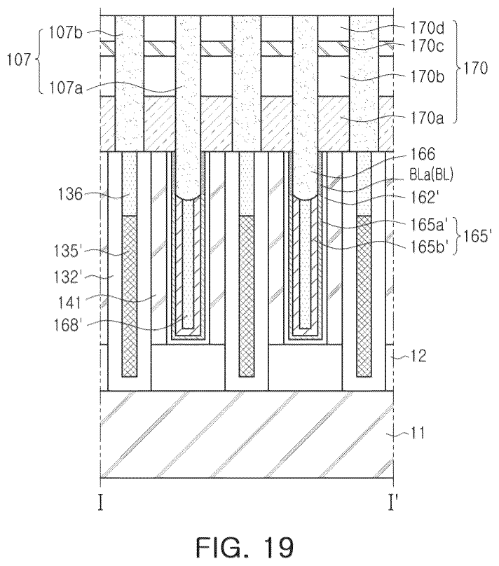

Referring to FIG. 19, contact patterns 170 may be formed in the plurality of openings OP.

In an example embodiment, an epitaxy process may be performed on an exposed upper surface of the vertical conductive layers 141, and a planarization process may be performed to form a first contact layer 170a, and second to fourth contact layers 170b, 170c, and 170d may be formed on the first contact layer 170a to prepare each of the contact patterns 170. In the epitaxy process, since impurities may be injected together, the first contact layer 170a may be a doped semiconductor layer. Additionally, the impurities may move to the vertical patterns 140 through diffusion in the epitaxy process or a subsequent process, thereby forming a second source/drain region 140SD2 (see FIG. 3A).

A method of manufacturing the contact patterns 170 and the number of layers and materials forming the contact patterns 170 may be changed.

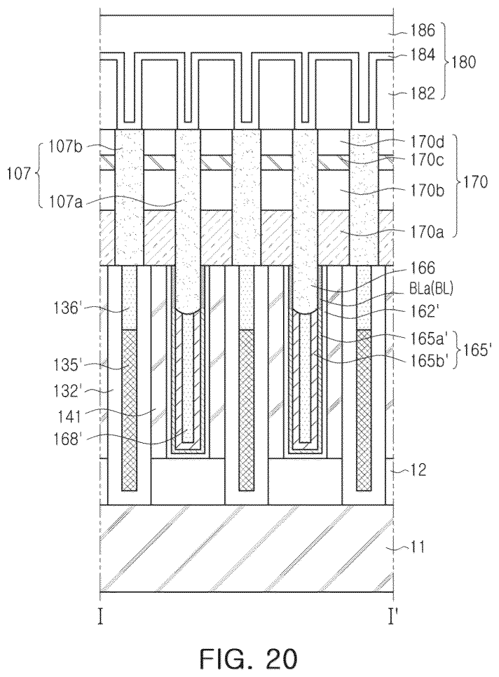

Referring to FIG. 20, an information storage structure 180 including lower first electrodes 182 electrically connected to the contact patterns 170 may be formed on the upper insulating layer 107.

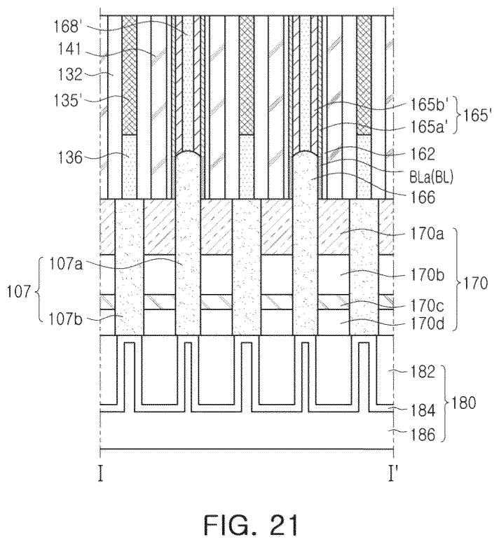

Referring to FIG. 21, the semiconductor structure according to FIG. 20 may be provided to be turned over, and the lower semiconductor layer 11 and the insulating layer 12 may be removed by a planarization process.

The semiconductor structure according to FIG. 20 may be provided to be turned over. Therefore, the information storage structure 180 may be located at the bottom, and the lower semiconductor layer 11 and the insulating layer 12 may be located at the top.

Thereafter, the lower semiconductor layer 11 and the insulating layer 12 may be removed by a planarization process, and upper surfaces of the preliminary back gate electrode 135′ and the preliminary gate electrode 165′ may be exposed.

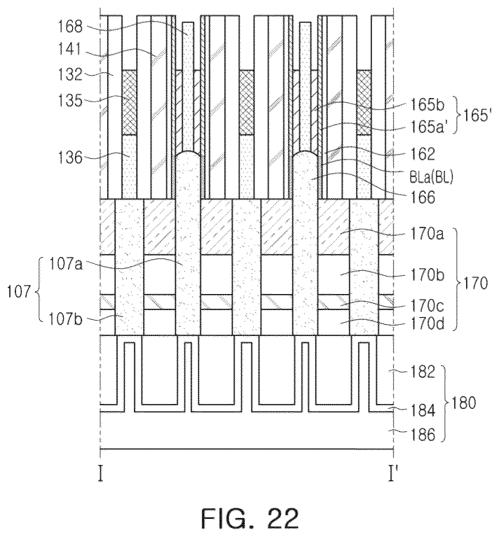

Referring to FIG. 22, upper regions of the preliminary back gate electrode 135′ and the preliminary gate electrode 165′ exposed by the planarization process may be removed by an etch-back process.

Through the etch-back process, a back gate electrode 135 and a gate electrode material layer 165b may be formed. According to an example embodiment, the preliminary back gate electrode 135′ and the preliminary gate electrode material layer 165b′ of the preliminary gate electrode 165′ may be removed together by the etch-back process. As necessary, the preliminary back gate electrode 135′ and the preliminary gate electrode material layer 165b′ may be removed in different orders. Therefore, an upper region of the preliminary gate electrode liner 165′ may be exposed.

By the etch-back process, a portion of an upper region of the preliminary insulating layer 168′ may be removed, and thus an insulating layer 168, as in FIG. 2, may be formed.

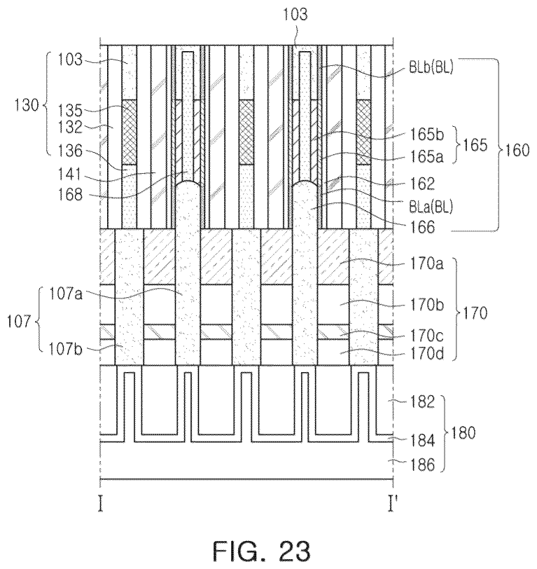

Referring to FIG. 23, at least a portion of the preliminary gate electrode liner 165′ may be oxidized to form a barrier layer BL.

Referring to FIG. 23, the upper region of the preliminary gate electrode liner 165′ exposed according to FIG. 22 may be selectively oxidized. Therefore, the second portion BLb of the barrier layer BL may be formed (see FIG. 3A).

Afterwards, an intermediate insulating layer 103 may be formed on an upper surface of the back gate electrode 135 and an upper surface of the gate electrode material layer 165b. Referring to FIG. 3A together, the intermediate insulating layer 103 may have a configuration corresponding to an intermediate insulating layer 103. According to an example embodiment, a planarization process may be performed to planarize a surface of the intermediate insulating layer 103.

Referring to FIGS. 23 and 3A together, back gate structures 130 and gate structures 160, according to the present inventive concept, may be formed.

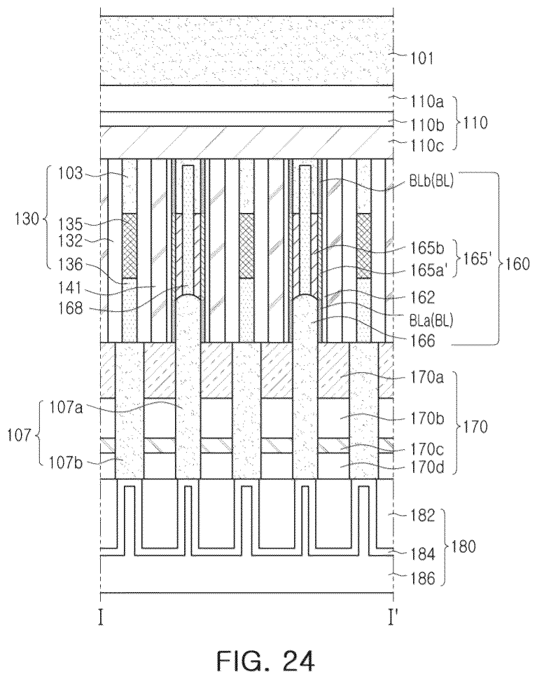

Referring to FIG. 24, a bit line structure 110 and lower insulating layers 101 may be sequentially formed on the back gate structures 130 and the gate structures 160. Thereafter, a semiconductor structure according to FIG. 24 may be provided to be turned over again, and a semiconductor device 100 according to the present inventive concept may be provided.

A semiconductor device 100a, as in FIG. 4, may be manufactured according to a process sequence identical or similar to the manufacturing method of the semiconductor device 100 described with reference to FIGS. 8 to 24.

First, the semiconductor device 100a, as in FIG. 4, may be prepared in the same manner as the manufacturing method of the semiconductor device described with reference to FIGS. 8 to 14.

Afterwards, a portion of an exposed surface of a preliminary gate electrode liner 165a′ (see FIG. 14) may be removed by an additional etch-back process.

Subsequently, similar to FIG. 15, a preliminary insulating layer 166′ may be formed in a gate trench GT.

Afterwards, the semiconductor device 100a may be provided through the same process sequence as in FIGS. 16 to 24 (see FIG. 4).

A semiconductor device 100b, as in FIG. 5, may be manufactured according to a process sequence similar to the manufacturing method of the semiconductor device 100 described with reference to FIGS. 8 to 24.

First, the semiconductor device 100b, as in FIG. 5, may be prepared in the same manner as the semiconductor device manufacturing method described with reference to FIGS. 8 to 22.

After this, a remaining insulating layer 168 may be removed by an additional etch-back process. Therefore, an upper surface of the insulating layer 168 may be located at substantially the same level as an upper surface of the gate electrode 165.

Afterwards, the semiconductor device 100b may be provided by the same process sequence as in FIGS. 23 and 24 (see FIG. 5).

A semiconductor device 100c, as in FIG. 6, may be manufactured according to a process sequence similar to the manufacturing method of the semiconductor device 100 described with reference to FIGS. 8 to 24.

First, the semiconductor device 100c, as in FIG. 6, may be prepared in the same manner as the semiconductor device manufacturing method described with reference to FIGS. 8 to 14.

Afterwards, at least a portion of a preliminary gate electrode liner 165a′ may be oxidized to form a preliminary barrier layer BL, and a preliminary insulating layer 166′ may be formed in a gate trench GT. In the present embodiment, the preliminary insulating layer 166′ containing an oxide, for example, silicon oxide, may be formed. Remaining processes may be the same as that described with reference to FIG. 15 for manufacturing the semiconductor device 100.

Subsequently, the same process sequence as in FIGS. 16 and 22 may be performed.

Thereafter, at least a portion of a preliminary gate electrode liner 165′ may be oxidized to form a barrier layer BL, and an intermediate insulating layer 103 may be formed on an upper surface of a back gate electrode 135 and an upper surface of a gate electrode material layer 165b. In the present embodiment, an intermediate insulating layer 103′ containing an oxide, for example, silicon oxide, may be formed. Remaining processes may be the same as that described with reference to FIG. 23 for manufacturing the semiconductor device 100.

Afterwards, the semiconductor device 100c may be provided through the same process sequence as in FIG. 24 (see FIG. 6).

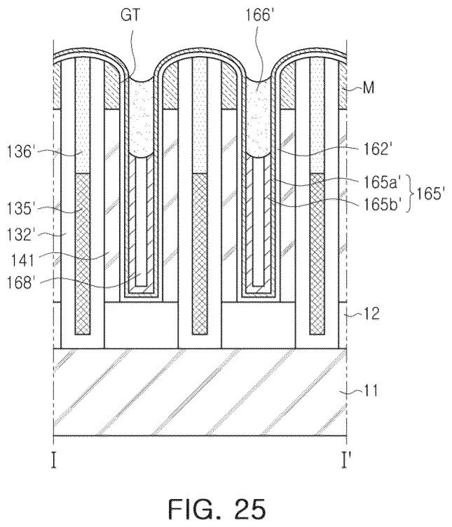

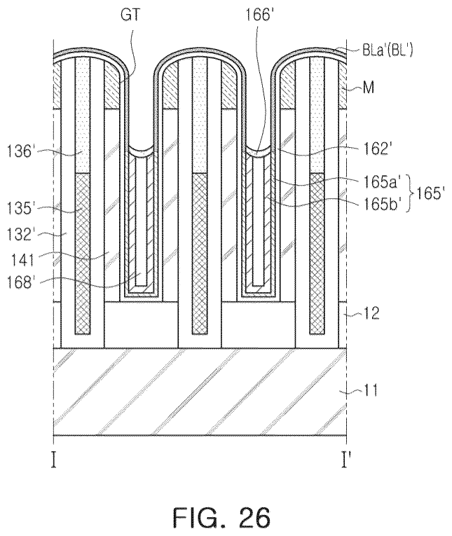

FIGS. 25 and 26 are vertical cross-sectional views illustrated according to a process sequence to explain a method of manufacturing a semiconductor device 100d according to an example embodiment. FIGS. 25 and 26 may be process diagrams illustrating subsequent processes following FIG. 14.

Referring to FIG. 25, a preliminary insulating layer 166′ may be formed within a gate trench GT.

Referring to FIG. 25, compared to FIG. 15, the preliminary insulating layer 166′ may be formed in the gate trench GT before oxidizing an exposed surface of a preliminary gate electrode liner 165a′.

Referring to FIG. 26, at least a portion of the preliminary insulating layer 166′ may be removed by an etch-back process, and at least a portion of the preliminary gate electrode liner 165a′ may be oxidized.

Referring to FIG. 26, an etch-back process may be performed such that a small amount of the preliminary insulating layer 166′ remains on a preliminary gate electrode material layer 165′. The small amount of the preliminary insulating layer 166′ remaining through the etch-back process may be a layer for preventing a preliminary gate electrode material layer 165b′ from being unnecessarily oxidized in a subsequent oxidation process.

By the etch-back process, a sidewall portion of an upper region of the preliminary gate electrode material layer 165′ may have a tapering structure (see FIG. 7). Afterwards, the upper region of the preliminary gate electrode material layer 165′ may be selectively oxidized.

Subsequently, the preliminary insulating layer 166′ may be formed again in the gate trench GT, and the semiconductor device 100d may be provided through the same process sequence as in FIGS. 16 to 24 (see FIG. 7).

According to embodiments of the technical idea of the present inventive concept, a semiconductor device including at least one barrier layer above and/or below a gate electrode may be provided. Therefore, a semiconductor device including at least one barrier layer to prevent and minimize current leakage that may occur between a gate electrode and a bit line structure and/or between the gate electrode and contact patterns may be provided. Additionally, since the at least one barrier layer may be formed by oxidizing the liner portion of the gate electrode, no separate process other than the oxidation process is required.

Various advantages and effects of the present inventive concept are not limited to the above-described contents, and can be more easily understood through description of specific embodiments of the present inventive concept.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a bit line structure extending in a first horizontal direction;
a first vertical pattern and a second vertical pattern, disposed on the bit line structure and spaced apart from each other;
a first back gate structure and a second back gate structure, respectively extending in a second horizontal direction intersecting the first horizontal direction, and parallel to each other, on the bit line structure; and
a plurality of gate structures between the first back gate structure and the second back gate structure,
wherein each of the first and second vertical patterns includes:
a first source/drain region electrically connected to the bit line structure;
a second source/drain region on a level higher than that of the first source/drain region; and
a vertical channel region between the first and second source/drain regions,
wherein the vertical channel regions of the first and second vertical patterns are disposed between the first and second back gate structures,
wherein the plurality of gate structures include a first gate structure adjacent to the first vertical pattern, and a second gate structure adjacent to the second vertical pattern,
wherein the first gate structure includes:
a first gate electrode including a first liner on the first vertical pattern and a first gate electrode material layer on the first liner;
a first gate dielectric layer including a portion disposed between the first vertical pattern and the first gate electrode; and
at least one first barrier layer extending along at least one side of the first liner on the first gate dielectric layer, and
wherein the second gate structure includes:
a second gate electrode including a second liner on the second vertical pattern and a second gate electrode material layer on the second liner;
a second gate dielectric layer including a portion disposed between the second vertical pattern and the second gate electrode; and
at least one second barrier layer extending along at least one side of the second liner on the second gate dielectric layer.

2. The semiconductor device of claim 1,
wherein the at least one first barrier layer comprises a plurality of first barrier layers, and the at least one second barrier layer comprises a plurality of second barrier layers,
wherein the plurality of first barrier layers include a first portion extending from a first surface of the first liner on the first gate dielectric layer, and a second portion extending from a second surface of the first liner, opposite to the first surface of the first liner, and
wherein the plurality of second barrier layers include a first portion extending from a first surface of the second liner on the second gate dielectric layer, and a second portion extending from a second surface of the second liner, opposite to the first surface of the second liner.

3. The semiconductor device of claim 2,
wherein a horizontal width of the first portion of each of the plurality of first barrier layers and a horizontal width of the first portion of each of the plurality of the second barrier layers are decreased, as a distance from the first surfaces of the first and second liners increases, and
wherein a horizontal width of the second portion of each of the plurality of first barrier layers and a horizontal width of the second portion of each of the plurality of second barrier layers are decreased, as a distance from the second surfaces of the first and second liners increases.

4. The semiconductor device of claim 2, further comprising:
a plurality of insulating layers disposed between the first gate structure and the second gate structure,
wherein the plurality of insulating layers include:
an insulating layer between the first gate electrode and the second gate electrode;
a first capping layer disposed between the first portion of the plurality of first barrier layers and the first portion of the plurality of second barrier layers and contacting an upper region of the insulating layer; and
a second capping layer disposed between the second portion of the plurality of first barrier layers and the second portion of the plurality of second barrier layers and contacting a lower region of the insulating layer.

5. The semiconductor device of claim 4,
wherein a lower surface of the insulating layer of the plurality of insulating layers is on a lower level than a lower surface of the first gate electrode material layer of the first gate electrode and a lower surface of the second gate electrode material layer of the second gate electrode, and
wherein the second capping layer is in contact with side and lower surfaces of the insulating layer.

6. The semiconductor device of claim 4,
wherein a lower surface of the insulating layer of the plurality of insulating layers is on substantially the same level as a lower surface of the first gate electrode material layer of the first gate electrode and a lower surface of the second gate electrode material layer of the second gate electrode, and
wherein the second capping layer is in contact with the lower surface of the insulating layer and the lower surfaces of the first and second gate electrode material layers.

7. The semiconductor device of claim 4,
wherein, in cross-sectional view, the upper region of the insulating layer has a downwardly concave shape, and
wherein a lower region of the first capping layer has a downwardly convex shape.

8. The semiconductor device of claim 4,
wherein the first and second capping layers comprise the same material, and
wherein the insulating layer comprises a material, different from the first and second capping layers.

9. The semiconductor device of claim 4, wherein the first and second capping layers and the insulating layer comprise an oxide.

10. The semiconductor device of claim 1,
wherein the at least one first barrier layer comprises a first lower barrier layer extending from a lower surface of the first liner on the first gate dielectric layer, and
wherein the at least one second barrier layer comprises a second lower barrier layer extending from a lower surface of the second liner on the second gate dielectric layer.

11. The semiconductor device of claim 10, further comprising:
a plurality of insulating layers disposed between the first gate structure and the second gate structure,
wherein the plurality of insulating layers include:
an insulating layer including a portion disposed between the first gate electrode and the second gate electrode, and having a protrusion protruding from a lower surface of the portion;
a first capping layer disposed in an upper portion of the insulating layer and contacting upper surfaces of the first and second gate electrodes; and
a second capping layer disposed between the first lower barrier layer and the second lower barrier layer and contacting a surface of the protrusion of the insulating layer.

12. The semiconductor device of claim 1,
wherein the first and second gate electrode material layers comprise molybdenum (Mo), and
wherein the first and second liners comprise the same material, and the first and second liners are selected from the group consisting of TiSiN, TaSiN, TiN, or TaN.

13. The semiconductor device of claim 1,
wherein the first and second liners comprise the same first material, wherein the first material is selected from the group consisting of TiSiN, TaSiN, TiN, or TaN, and
wherein the at least one first barrier layer and the at least one second barrier layer comprise the same second material, wherein the second material is an oxide of the first material.

14. A semiconductor device comprising:
a vertical pattern including a first source/drain region, a second source/drain region on a level higher than that of the first source/drain region, and a vertical channel region between the first and second source/drain regions;
a back gate structure facing a first side surface of the vertical pattern; and
a gate structure facing a second side surface, opposite to the first side surface of the vertical pattern,
wherein the back gate structure includes:
a back gate electrode on the first side surface of the vertical pattern; and
a back gate dielectric layer including a portion disposed between the vertical pattern and the back gate electrode, and
wherein the gate structure includes:
a gate electrode including a gate electrode liner on the second surface of the vertical pattern and a gate electrode material layer on the gate electrode liner;
a gate dielectric layer including a portion disposed between the vertical pattern and the gate electrode liner of the gate electrode; and
at least one barrier layer extending along at least one side of the gate electrode liner on the gate dielectric layer.

15. The semiconductor device of claim 14, wherein the gate electrode liner of the gate electrode and the at least one barrier layer have a liner shape.

16. The semiconductor device of claim 14,
wherein the at least one barrier layer comprises a plurality of barrier layers, and
wherein the plurality of barrier layers include a first portion extending from a first surface of the gate electrode liner on the gate dielectric layer, and a second portion extending from a second surface of the gate electrode liner, opposite to the first surface.

17. The semiconductor device of claim 16,
wherein the gate structure further comprises a gate capping layer on the gate electrode material layer of the gate electrode,
wherein the gate capping layer extends along one side of the first portion and one side of the second portion of the plurality of barrier layers.

18. The semiconductor device of claim 16, wherein a thickness of the first portion and a thickness of the second portion of the plurality of barrier layers are reduced, as a distance from the gate electrode liner increases.

19. A semiconductor device comprising:
a vertical pattern including a first source/drain region, a second source/drain region on a level higher than that of the first source/drain region, and a vertical channel region between the first and second source/drain regions; and
a gate structure disposed on a first side surface of the vertical pattern,
wherein the gate structure includes:
a gate electrode including a gate electrode liner on the first surface of the vertical pattern and a gate electrode material layer on the gate electrode liner;
a gate dielectric layer including a portion disposed between the vertical pattern and the gate electrode liner of the gate electrode; and
at least one insulating barrier layer extending along at least one side of the gate electrode liner on the gate dielectric layer, and
wherein the at least one insulating barrier layer has a liner shape with the gate electrode liner.

20. The semiconductor device of claim 19, further comprising:
a back gate structure facing a second side surface, opposite to the first side surface of the vertical pattern,
wherein the back gate structure includes:
a back gate electrode on the second surface of the vertical pattern; and
a back gate dielectric layer including a portion disposed between the vertical pattern and the back gate electrode.
